(19) United States
(12) Patent Application Publication
(10) Pub. No.: US 2024/0234871 A1
(43) Pub. Date: Jul. 11, 2024

(54) THERMAL MANAGEMENT OF A LIQUID COOLED MODULE

(71) Applicant: APR Technologies AB, Enköping (SE)

(72) Inventors: Are BJÖRNEKLETT, Västerås (SE); Patrik LUNDIN, Solna (SE); Elisabeth SÖDERLUND, Ekolsund (SE); Peter NILSSON, Sundbyberg (SE); Robert THORSLUND, Sigtuna (SE)

(21) Appl. No.: 18/558,760

(22) PCT Filed: May 5, 2022
(86) PCT No.: PCT/SE2022/050435

§ 371 Date: Nov. 3, 2023

(30) Foreign Application Priority Data
May 6, 2021 (SE) 2150581-3

(51) Int. Cl. H01M 10/6568; F28F 9/02; H01M 10/613; H01M 50/213; H01M 50/242

(52) U.S. Cl. CPC H01M 10/6568; F28F 9/0278; H01M 10/613; H01M 50/213; H01M 50/242

(57) ABSTRACT

Described is among other things a liquid cooled module (1). The liquid cooled module provides improved heat dissipation and improved flow in the liquid cooled module (1).

### TECHNICAL FIELD

The present invention relates to a liquid cooled module comprising a housing, a plurality of heat generating components arranged in the housing, and a liquid for thermal management of the heat generating components.

### BACKGROUND

There is an increased use of heat generating devices such as electric components and rechargeable batteries. Applications include for example, energy storage, energy transformation to powering electric equipment and vehicles or as a power back up in stationary applications. During operation, the heat generating components generate heat which needs to be dissipated effectively to allow safe functioning of the components and prevent failure of the module in which such heat generating components are housed. The performance of the heat generating component is to a large extent limited by the available thermal management techniques for keeping the component within an appropriate temperature range.

In for example battery applications, it is known to have thermal management systems employed within the battery module to control the operational temperature of the battery cells within an optimal temperature range.

Increased energy storage capacity and reduced charging times have led to a strive for more efficient thermal management in general, and dissipation of generated heat in particular. One commonly employed thermal management method is known as immersion cooling, which also referred to as liquid submersion cooling. This is the practice of submerging components, such as e.g., battery cells, in a thermally conductive liquid. Thus, the heat may be transferred directly from the heat source, e.g., battery cell, electronics, printed circuit board, to the working fluid and dissipated through a heat exchanger located elsewhere.

With the ever-increasing performance requirements regarding storage capacity and strive for more space efficient systems, there is a need for improved and more efficient thermal management techniques.

US2020266506 discloses a battery module including a housing and a plurality of battery cells arranged in a battery stack received within the housing. The battery cells are rectangular and has two parallel main surfaces. The battery modules in the stack are arranged so that the main surfaces of neighboring cells in the stack is in close contact with each other. The battery module further includes an inner cover disposed between the housing and the plurality of battery cells. The inner cover includes a top surface facing the housing and a bottom surface facing the plurality of battery cells. The inner cover also includes a plurality of fluid channels defined on the bottom surface and extending along a length of the inner cover. Each of the plurality of fluid channels is configured to receive a fluid, such as a thermal management liquid. The fluid channels lead the fluid from one side of the battery cell to the opposite side of battery cell in a direction perpendicular to the main surfaces of the battery cells and by that improve the circulation of the fluid within the battery module. The inner cover is also provided with openings disposed above the battery cells for letting out gases generated by the battery cells.

U.S. Pat. No. 4,522,898 discloses a battery with a housing containing a plurality of battery cell as well as a cooling medium. The battery cells are cylindrical and arranged adjacent to each other with their longitudinal axes in parallel so that elongated spaces for housing the cooling medium are formed between the battery cells. The battery comprises a distributor plate provided in the interior of the housing for feeding and distributing the cooling medium to the battery cells. The distributor plate is provided with openings through which the cooling medium can be fed to the spaces between the battery cells. The distributor plate is disposed either above the upper ends of the battery cells or below the lower ends of the battery cells. The cooling medium is inlet to an open space above the battery cells. The cooling medium flows through the openings in the distributor plate and in the elongated spaces between the battery cells. This battery is mainly intended with air as a medium.

Also, US2014/0162106 describes a cooling arrangement for a battery where cooled medium is sprayed upon the connector plate of the battery to cool the terminals of the cells in the battery.

There is a constant desire to improve the thermal management of liquid cooled modules and to thereby increase the performance of the heat generating components housed inside the module. Hence there is a need for an improved liquid cooled module.

### SUMMARY

It is an aim of the present invention to at least partly overcome the above problems, and to provide an improved thermal management of a liquid cooled module.

This aim is achieved by a liquid cooled module in accordance with the appended claims.

In accordance with one aspect a liquid cooled module comprising a plurality of heat generating components arranged so that spaces for housing a moving fluid are formed around the heat generating components is provided. The liquid cooled module has a liquid sealed casing enclosing the heat generating components. At least one restricting member is located in the flow path the moving fluid. The restricting member can be placed in the spaces. By placing a member/element in the flow path the flow around the heat generating components such as battery cells can be improved. Restricting members can typically be placed in a plurality or all of the spaces. In another embodiment a manifold is used as a restricting member to aid in improving the distribution of the moving fluid. Other types of restricting members can also be used. The use of a restricting member leads to an improved heat transport and the heat generating components can be cooled more efficiently. The plurality of heat generating components can advantageously be cylindrical in shape to allow for an efficient space use, but other shapes such as prism shapes are also possible.

In accordance with some embodiments a pump for pumping the fluid is located inside the liquid sealed casing. Hereby the liquid cooled module can be self-contained and no parts external to the casing are required. For example, the liquid cooled module can then be used as a liquid cooled (stand-alone) battery pack that can easily be moved around and used as a power back-up in a car or at a home. The pump can for example be an Electrohydrodynamic (EHD) pump. Typically, the fluid is moved in an axial direction of the heat generating components in fluid channels formed in the spaces and the length of the fluid channels correspond to the axial length of the heat generating components or at least almost the length of the heat generating components such as at least 80% of the length of the heat generating components.

In accordance with some embodiments, the pump is cylindrical in shape. Hereby the use of space inside the casing of the liquid cooled module can be improved when other components such as battery cells also are cylindrical.

In accordance with some embodiments, the restricting members are pin shaped and located in the spaces between the heat generating components. Hereby a good flow restriction can be achieved and the restricting members can be designed to have additional functions such as to allow thermal expansion of the heat generating components.

In accordance with some embodiments, the liquid cooled module comprises a distributor plate disposed between the casing and the heat generating components. The distributor plate is provided with a plurality of openings for distributing the fluid to the spaces between the heat generating components and a manifold structure comprising a plurality of fluid channels arranged between the at least one fluid entrance and a distributor plate to guide the fluid from the at least one fluid entrance to the openings in the distributor plate. The manifold can act as a restricting member to improve the distribution of the moving fluid. Hereby a more even and thereby improved distribution of liquid over all heat generating components can be obtained. Further, when a manifold structure is provided, the manifold structure can be integrated in some part of the casing. Hereby manufacturing and assembly is facilitated.

In accordance with some embodiments, each of the fluid channels has an open side facing the distributor plate, and the distributor plate is tightly attached to the manifold structure so that the open sides of the channels are partly sealed by the distributor plate. Hereby the cooling can be improved.

In accordance with some embodiments, the distributor plate is made of an electrically conducting material and is configured to act as an electrical connector/connector plate. Hereby the distributor plate can be made to have multiple functions and there is need for a separate electrical connector.

In accordance with some embodiments, at least one at least partly cylindrical shaped thermal expansion compensating structure is provided. This can be a separate part or it can be formed by the restricting members, or both. For example, the restricting members can be formed by an elastic material to allow for thermal expansion.

In accordance with some embodiments, the restricting members are formed by an electric conductive material to allow for electric connection.

In accordance with some embodiments, the liquid sealed casing comprises flanges and or at least one corrugated section. Hereby thermal dissipation can be improved and heat can be let out via the casing. This is particularly useful when there is no liquid inlet/outlet from the liquid cooled module in that heat then can be efficiently let out from the liquid cooled module.

In accordance with some embodiments, at least one partly cylindrical heat sink member located on a wall of the casing or at the bottom of the casing, and where at least one partly cylindrical heat sink member is provided with at least one flange. Hereby heat dissipation can be improved by using space not used inside the liquid cooled casing to facilitate heat dissipation.

In accordance with some embodiments, the restricting members comprise a hollow section allowing compression of the restricting members. Hereby compression of the restricting members is eased.

In accordance with some embodiments, the restricting members are formed by an electrically isolating material. Hereby efficient isolation between heat generating components can be obtained.

In accordance with one aspect of the invention a liquid cooled module, in particular a battery module comprises a plurality of battery cells arranged so that spaces for housing a fluid are formed between the battery cells, a casing enclosing the battery cells, wherein the casing is provided with at least one fluid entrance, and a distributor plate disposed between the casing and the battery cells and provided with a plurality of openings for distributing the fluid to the spaces between the battery cells. According to this aspect, the module comprises a manifold structure comprising a plurality of fluid channels arranged between the at least one fluid entrance and the distributor plate to guide the fluid from the at least one fluid entrance to the openings in the distributor plate.

The channels in the manifold structure and the distributor plate make it possible distribute the fluid from the at least one fluid inlet evenly to the spaces between the battery cells. The fluid channels make it possible to control the flow of fluid between the fluid entrance and the openings. Thus, turbulence in the fluid flow can be avoided and the temperature management of the battery model is improved. The temperature variation between different battery cells within the battery module is controlled and can be minimized. Further, the distance the fluid must travel is reduced, which leads to a controlled temperature in the fluid. Another advantage with the battery module is that the fluid channels can be designed so that the pressure drop in the fluid is reduced.

The fluid channels are arranged in the manifold structure which serves as a mechanical structure housing the fluid channels. The manifold structure makes it easy to manufacture the channels.

The openings in the distributor plate are arranged to correspond to the positions of the spaces between the battery cells so that the flow of fluid is guided towards the spaces between the battery cells. Thus, the flow of fluid can be evenly distributed between the battery cells.

According to one aspect, the battery cells are elongated and arranged with their longitudinal axes in parallel. Thus, the spaces between the battery cells are elongated and arranged in parallel.

According to an aspect, the battery cells are cylindrical and arranged with their symmetry axes in parallel.

According to an aspect, the fluid channels are elongated and extend in a plane perpendicular to the axes of the battery cells.

According to an aspect, the distributor plate and accordingly the plurality of openings in the distributor plate is arranged below or above the spaces between the battery cells.

According to an aspect of the invention, the manifold structure is plate shaped and defines a plane. The plurality of fluid channels is arranged so that they extend in the plane defined by the manifold structure.

According to an aspect of the invention, each of the fluid channels has an open side facing the distributor plate, and the distributor plate is tightly attached to the manifold structure so that the open sides of the channels are partly sealed by the distributor plate.

In one aspect, each of the fluid channels extend over one or more of the openings in the distributor plate or ends in one of the openings in the distributor plate so that the openings in the distributor plate are in fluid communication with the fluid channels.

According to an aspect of the invention, the distributor plate is made of an electrically conducting material, and the distributor plate has an additional function as electrical connector. The distributor plate is electrically connected to at least some of the battery cells.

According to an aspect of the invention, the manifold structure has a bottom surface facing the distributor plate, the plurality of fluid channels defines elongated openings in the bottom surface of the manifold structure, and the distributor plate is tightly attached to the manifold structure so that the elongated openings in the bottom surface of the manifold structure are partly sealed by the distributor plate. The elongated openings in the manifold structure are arranged so that they face the openings in the distributor plate so that the fluid in the fluid channels can leave the channels through the openings in the distributor plate. Each elongated opening in the manifold structure faces one or more of the openings in the distributor plate. Thus, one fluid channel may supply fluid to one or more openings in the distributor plate. The parts of the elongated openings, which do not face the openings in the distributor plate, are sealed by the distributor plate. Thus, the distributor plate forms the bottoms of the fluid channels. This aspect makes it easy to manufacture the fluid channels.

According to an aspect of the invention, the distributor plate is made of a flexible material and the distributor plate is pressed against the manifold structure.

According to an aspect of the invention, the casing comprises a first wall arranged on one side of the battery cells, and the manifold structure is attached to the first wall. To have a separate manifold structure makes it easy to manufacture the manifold structure.

According to an aspect of the invention, the fluid channels have an upper side facing the first wall and a lower side facing the distributor plate. The upper sides of the fluid channels are opened and form elongated openings in an upper surface of the manifold structure, which elongated openings are facing the first wall. The lower sides of the fluid channels are opened and form elongated openings in a bottom surface of the manifold structure, which elongated openings are facing the distributor plate. The distributor plate is tightly attached to the manifold structure so that the elongated openings in the bottom surface of the manifold structure are partly sealed by the distributor plate. The fluid channels are defined by the first wall, the manifold structure, and the distributor plate. The upper surface of the manifold structure is tightly attached to the first wall so that the elongated openings in the upper surface of the manifold structure are sealed by the first wall. Thus, the first wall and the distributor plate seal the fluid channels in the manifold structure. This aspect facilities the manufacturing of the fluid channels.

According to an aspect of the invention, the battery cells are elongated and arranged in parallel, and the first wall is arranged perpendicular to the longitudinal axes of the battery cells.

According to an aspect of the invention, the at least one flow entrance is arranged in the first wall.

According to an aspect of the invention, the at least one flow entrance is arranged between the first wall and the manifold structure.

According to an aspect of the invention, the casing comprises a second wall arranged on an opposite side of the battery cells, and the second wall is provided with at least one fluid outlet. In this embodiment, the flow entrance and the flow outlet are arranged above and below the battery cells, respectively. Thus, the flow of fluid in the spaces between the battery cells is parallel to the axial direction of the battery cells, and in direct contact with the envelop surface of the individual battery cells. This will provide an efficient cooling of the batteries.

According to an aspect of the invention, the manifold structure is integrated into the first wall. Thus, the fluid channels are arranged in a wall of the casing. This will reduce the number of parts of the battery module.

According to an aspect of the invention, the at least one fluid entrance is arranged at a distance from the edges of the first wall, and the first wall is provided with an inlet channel arranged between one edge of the first wall, and the fluid entrance for supplying the fluid to the fluid entrance. Preferably, the fluid entrance is arranged in a central part of the first wall. Thus, the distance the fluid needs to travel from the fluid entrance to the spaces between the battery cells is reduced, which leads to a controlled temperature raise of the fluid.

According to an aspect of the invention, the cross-section areas of the fluid channels are decreasing further away from the fluid entrance. The fluid channels become narrower further away from the fluid entrance. Thus, the cross-section areas of the fluid channels are decreasing towards the ends of the channels. This aspect will decrease the pressure in the channels. Also, the liquid flow will be better balanced and distributed.

According to an aspect of the invention, at least some of the channel's branches into a plurality of narrower channels passing at least one of the opening of the distributor plate.

According to an aspect of the invention, the channels are smoothly bent. Sharp bents are avoided. The shapes of the channels are balanced through smooth bends to avoid turbulence and to control the pressure. This aspect provides a reduced flow disturbance and minimizes the flow resistance.

According to an aspect of the invention, the casing is provided with at least one fluid outlet, the battery comprises a collector plate disposed between the casing and the battery cells on an opposite side of the battery cells with respect to the distributor plate, the collector plate is provided with a plurality of openings for receiving the fluid from the spaces between the battery cells, and the battery module comprises a second manifold structure arranged between the collector plate and the at least one fluid outlet, and the second manifold structure comprises a plurality of second fluid channels arranged to guide the fluid from the openings in the collector plate to the at least one fluid outlet.

According to an aspect of the invention, the battery comprises at least one cell holder for holding and supporting the battery cells, and the cell holder comprises a plurality of through holes for holding the battery cells and a plurality of openings disposed between the through holes to allow the fluid to pass through the cell holder. In one aspect, the openings in the cell holder are aligned with the openings in the distributor plate. The cell holder ensures a minimum distance between battery cells and the openings in the cell holder allow for fluid flow in the axial direction of the battery cells. This aspect allows the fluid to pass through the cell holder. The flow of fluid in the spaces between the battery cells is improved and accordingly the cooling of the battery cells is improved.

According to an aspect of the invention, the at least one cell holder is arranged at upper and/or lower ends of the battery cells. This location of the cell holders is advantageous since the cell holder will not disturb the fluid flow along the surfaces of the battery cells. Accordingly, a laminar flow of fluid between the battery cells is achieved.

According to an aspect of the invention, the battery module comprises at least one electrical conductor adapted to provide electrical connection between a plurality of neighbouring battery cells, the electrical conductor comprise a plurality of openings aligned with the openings in the distributor plate to allow the fluid to pass through the electrical conductor.

According to an aspect, the electrical connectors are busbars. This aspect allows the fluid to pass through the electrical conductor improves the cooling of the battery cells.

According to an aspect, the electrical connectors are a metal sheet with a plurality of openings aligned with the openings in the distributor plate to allow the fluid to pass through the electrical conductor. According to an aspect, the electrical connectors are a flexifilm with printed circuits or a

Printed Circuity Board with a plurality of openings aligned with the openings in the distributor plate to allow the fluid to pass through the electrical conductor.

According to an aspect, the electrical connector with a plurality of openings has a multiple function as distributor plate and the openings are aligned with the volumes between the battery cells.

According to an aspect of the invention, the first wall is a lid of the casing. Thus, the fluid channels are a part of the lid of the casing.

### BRIEF DESCRIPTION OF THE DRAWINGS

The invention will now be explained more closely by the description of different embodiments of the invention and with reference to the appended figures.

FIG. 1 shows an example of battery module in a perspective view,

FIG. 2a shows a perspective view of an example of a stack of battery cells,

FIG. 2b shows the stack of battery cells in FIG. 2a from above,

FIG. 3 shows an example of a liquid cooled module in the form of a battery module in an exploded view,

FIG. 4 shows an example of a distributor plate,

FIG. 5a-c show examples of a manifold structures including channels for distributing a fluid in views from below,

FIG. 6 shows an example of a battery module including the manifold structure shown in FIG. 5a,

FIG. 7 shows another example of a battery module including any of the manifold structure shown in FIGS. 5b and 5c,

FIG. 8 shows the battery module in FIG. 7 from above,

FIG. 9 shows yet another example of a battery module in an exploded view,

FIG. 10 shows an example of a cell holder for holding the battery cells,

FIG. 11 shows an example of an electrical conductors connected to the battery cells,

FIGS. 12 and 13 illustrate a restricting member,

FIG. 14 illustrates a pump inside the casing of a liquid cooled module,

FIG. 15 illustrates a heat sink member,

FIG. 16 is a top cross-sectional view of a liquid cooled module,

FIGS. 17-19 illustrate different air bubble trap arrangements,

FIG. 20 is a view illustrating flow of cooling liquid in a battery, and

FIG. 21 illustrate channels in the casing of a liquid cooled module.

### DETAILED DESCRIPTION

Aspects of the present disclosure will be described more fully hereinafter with reference to the accompanying drawings. In the following description a liquid cooled module with heat generating components is described. The heat generating components are in some of the exemplary embodiments set out to be battery cells. However, the heat generating components can be other types of heat generating components such as motors, electrical components, micro-processors, printed circuit boards etc. Further it is appreciated that different aspects of thermal management are described herein. It is to be understood that the different aspects can be used one by one, but also, preferably, in different combinations so as to achieve a good thermal management for the application at hand. Thus, even if some aspects are described in combination, the aspects can be applied without being combined. Likewise, aspects from different examples can be combined to improve the thermal management. Like numbers in the drawings refer to like elements throughout.

FIG. 1 shows an example of a liquid cooled module 1. The liquid cooled module in the example of FIG. 1 is a battery module 1 in a perspective view. A battery may include one or more battery modules electrically and fluidically connected to each other. The battery modules can be electrically connected to each other in series or in parallel. The battery module 1 can be used for storing and supplying electrical power to any electrical system, such as an electric vehicle, an industrial electrical system, and a stationary energy storage system. For explanatory purposes, a single battery module 1 will be explained in detail in the description provided below.

The battery module comprises a casing 2 enclosing a stack of heat generating components 5. In this example all of the heat generating components are battery cells 5. However, it is also envisaged that some or all of the heat generating components 5 could be other types of heat generating components 5. Also, not all components in the stack of heat generating components need to be heat generating, but could be of other types. In the illustrated embodiment, the casing 2 has a substantially hollow, and rectangular configuration. The casing 2 defines a first end 2a and a second end 2b disposed opposite the first end 2a. The casing 2 may have other configurations depending on application requirements. The casing also defines a length extending between the first end 2a and the second end 2b. The casing comprises a plurality of walls 3a-f, such as a first wall 3a, a second wall 3b disposed opposite the first wall 3a, a first end wall 3c disposed at the first end 2a of the housing 2, a second end wall 3d disposed at the second end 2b of the housing, and a front wall 3e, and a rear wall 3f. The first and second walls 3a-b are arranged in parallel and extends between the end walls 3c-d. The first wall 3a can, for example, be a lid of the casing, and the other walls defines a box-like bottom part of the casing 2. In such case, the first wall 3a can be removably attached to the bottom part of the casing or to an end wall thereof. The casing 2 can be made of any suitable material, such as a polymer, a metal for example Aluminum an alloy (such as an Aluminum-alloy), and the like. The casing 2 is sealed to hold a fluid inside the casing.

In the exemplary embodiment of FIG. 1, the casing 2 comprises at least one a fluid entrance 8 and at least one a fluid outlet 9. The fluid entrance 8 is an opening in the casing adapted to receive a flow of fluid into the housing 2. The fluid entrance 8 can be connected to an inlet port for the fluid. The fluid entrance is positioned between the first wall and the top level of battery cells. The casing can be provided with more than one fluid entrance 8 and more than one fluid outlet 9. The fluid outlet 9 is an opening in the casing 2 to allow the fluid to leave the casing 2. The fluid outlet 9 can be connected to an outlet port for the fluid. The fluid outlet is positioned between the second wall and the bottom level of battery cells. The fluid entrance and outlet can be switched, so that is the liquid is entering between the second wall and the bottom level of battery cells and leaving between the first wall and the top level of battery cells. The fluid may be any thermal management fluid, such as a dielectric liquid, a gas, or a combination of a liquid and a gas. In the illustrated embodiment, the fluid entrance 8 and the fluid outlet 9 are disposed in the front wall 3e. However, the fluid entrance 8 and the fluid outlet 9 can be arranged in any of the walls 3a-e, such as in the first wall 3a and the second wall 3b respectively, or in the first and second end walls 3c-d respectively. The fluid outlet 9 is disposed spaced apart from the fluid entrance 8. In alternative embodiments, the casing can have more than one fluid entrance 8 and more than one the fluid outlet 9 so that a plurality of battery cells can be fluidly connected to each other. The casing is also provided with two or more electric ports 10 to allow the battery module to be electrically connected to an external circuit and/or to other battery modules.

In accordance with an alternative embodiment, no fluid entrance/inlet or outlet is provided. In such an embodiment liquid can be pumped inside the casing and heat can be dissipated via the casing 2.

The battery module can in accordance with some embodiments be provided with a Battery Management System (BMS). The BMS is provided to balance the energy between different battery cells of the battery module. Typically, the aim of the BMS is to ensure that the energy of each battery cell is the same for each battery cell in relation to the capacity of each individual battery cell. The BMS can be passive where charging is by-passed battery cells determined to be fully charged or active where charging is distributed actively to charge each cell individually.

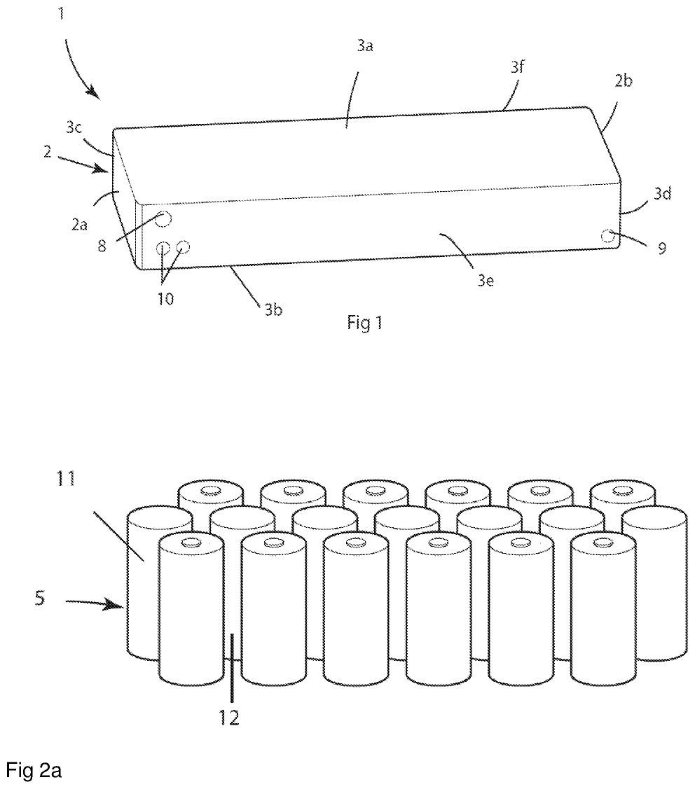

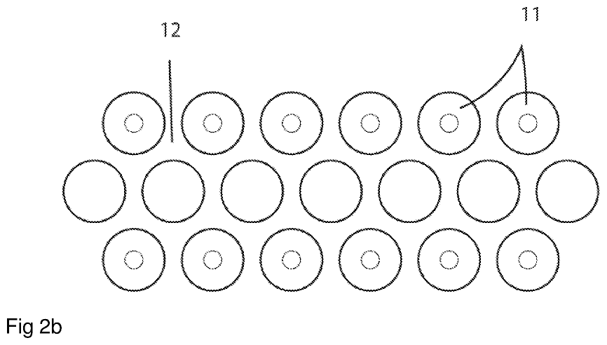

FIG. 2a shows a perspective view of an example of a stack 5 of components, in this example battery cells 11. With a stack 5 is meant a plurality of components arranged in a defined configuration. In the illustrated example, the components, here battery cells, are arranged in a hexagonal configuration. This configuration can for example be used for hexagonal battery cells. However, the components battery cells can be arranged in other configurations, such as a square configuration. This configuration can for example be used for prismatic battery cells. FIG. 2b shows the stack 5 of battery cells in FIG. 2a from above. The battery cells 11 are arranged so that spaces 12 for housing a fluid are formed between the battery cells 11. These spaces 12 form smooth fluid volumes without inflicting structures in the way for the fluid. The spaces 12 are typically formed between envelop surfaces of the battery cells. The spaces 12 then form elongated and parallel volumes between the battery cells, without inflicting structures in the way for the liquid/fluid used to cool the battery cells. The volumes can be seen as channels running in an axial direction from one side of the battery cells to the other side of the battery cells. The liquid/fluid used to cool the battery cells can be supplied to the spaces from a direction parallel to the orientation of the spaces 12. Thus, when the cooling fluid/liquid is supplied into the spaces 12, the feed of cooling liquid/fluid is in a direction parallel to the spaces. In FIG. 2a the liquid/fluid can be fed from above down into the elongated spaces 12 as will be described in more detail later. In the illustrated embodiment, the battery cells 11 are cylindrical. Each of the battery cells 11 have an axis of symmetry, an envelope surface facing the spaces 12, and upper and lower ends. In the illustrated embodiment, the battery cells 11 are elongated and the longitudinal axes of the battery cells coincides with the axes of symmetry. The battery cells 11 are arranged with their axis of symmetry in parallel. The spaces 12 form elongated and parallel channels between the battery cells, without disturbing structures. In alternative embodiments, the battery cells can have other shapes, such as rectangular, e. g. prismatic cells. The battery cells can be arranged in close vicinity to each other, or at a distance from each other so that the spaces 12 surround the battery cells. The spaces 12 form elongated and parallel volumes between the battery cells, without disturbing structures. In one aspect, the battery cells 11 are arranged perpendicular to the first and second walls 3a-b. Also, the number or battery cells 11 shown in the accompanying figure is merely exemplary and may vary based on application requirements. Thus, the cooling liquid/fluid can run freely along the sides of the battery cells 11 in the spaces 12 without any obstructing element in the way. The flow can also be in the opposite direction. For example, the flow can be from the bottom up. Thus, a flow in the axial direction of the battery cells 12 is achieved where the flow is unobstructed. In yet another embodiment the battery cells are located on both sides of the inlet/outlet of the cooling liquid/fluid. For example, one or two layers of battery cells can be located above the inlet/outlet of the cooling liquid/fluid and one or two layers of battery cells can be located below the inlet/outlet of the cooling liquid/fluid. In other embodiments further layers can be arranged, but the cooling efficiency will decrease the more battery cells the cooling liquid/fluid needs to cool before being cooled itself.

The battery cell 11 also includes one or more electric terminals to allow the battery cells to be electrically connected to each other. For example, the electric terminals are disposed at the upper ends of the battery cells. In the illustrated example, every second of the battery cells is turned upside down so that the some of the electrical terminals points downwards and some of the electrical terminals points upwards. This facilitates the electrical connection of the battery cells. The battery cells 11 may be any electrochemical cell, such as a Lithium-Ion type electrochemical cell, a Lithium-Polymer type electrochemical cell, solid state batteries, and the like. In an alternative embodiment, the battery module may include two or more layers of battery cells.

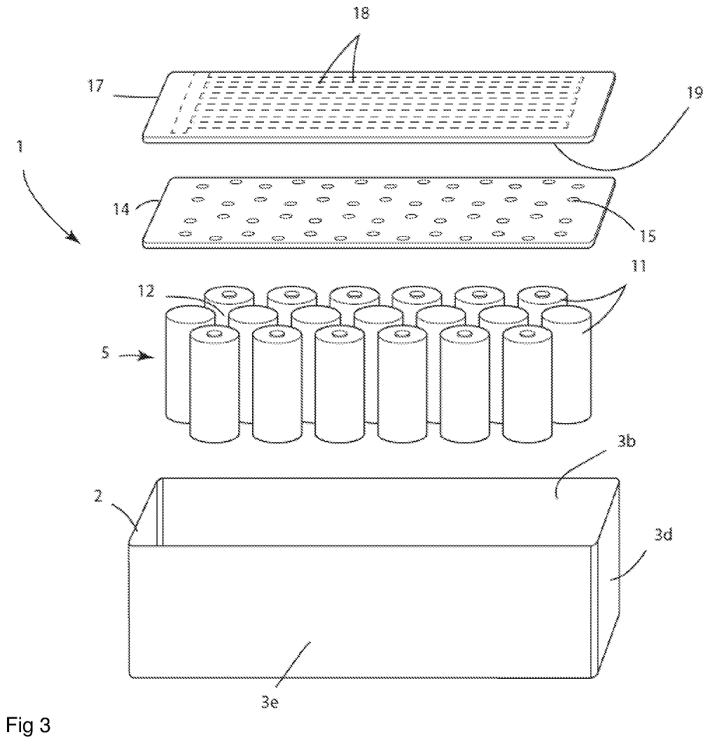

FIG. 3 shows an example of a battery module 1 according to an embodiment in an exploded view. The battery module 1 comprises a stack 5 including a plurality of cylindrical battery cells 11 arranged adjacent each other so that spaces 12 for housing a fluid is formed between the battery cells. The battery module 1 further comprises a distributor plate 14 provided with a plurality of openings 15 spaced apart from each other for distributing the fluid to the spaces 12 between the battery cells 11, and a manifold structure 17 comprising a plurality of fluid channels 18 arranged to guide the fluid between the at least one fluid entrance 8 in the casing 2 and the openings 15 in the distributor plate. The distributor plate 14 can to improve the flow path of the fluid moving in the liquid cooled module. Also, the manifold structure 17 can act as a restricting member to improve the flow path of the fluid moving in the liquid cooled module. The openings 15 in the distributor plate 14 are arranged to place the openings above or below regions in which the spaces 12 between the battery cells are located. The manifold structure 17 is arranged between the at least one fluid entrance 8 of the casing and the distributor plate 14. In one aspect of the invention, the manifold structure 17 is integrated into the first wall 3a. In another aspect, the manifold structure 17 is attached to the first wall 3a. Each of the fluid channels 18 in the manifold structure 17 is in fluid communication with the one or more fluid entrances 8 of the casing 2. The openings 15 in the distributor plate are in fluid communication with the at least one fluid entrance 8 via the fluid channels 18. When fluid/liquid flows in the spaces 12, the cells can be arranged so that the flow only cools one layer of cells and not multiple serially arranged cells. For example, one layer of battery cells 11 can be arranged above the inflow of fluid/liquid and one layer of battery cells can be arranged below the inflow of fluid/liquid. Hereby, the fluid will only flow a distance of about the axial length of the battery cells before being cooled. In this way all battery cells will be cooled equally.

The distributor plate 14 defines a plane arranged perpendicular to axes the battery cells 11. The distributor plate 14 is disposed either above the upper ends of the battery cells 11 and/or below the lower ends of the battery cells. Thus, the openings 15 in the distributor plate are either above and/or below the spaces between the battery cells so that the fluid will flow in parallel with the envelop surfaces of the battery cell in the axial directions of the battery cells 11. The positions of the plurality of openings 15 in the distributor plate 14 correspond to positions of the spaces 12. The openings 15 in the distributor plate 14 are preferably aligned with the spaces 12 between the battery cells so that the fluid enters the spaces 12 between the battery cells 11 and flows along the surfaces of the battery cells. There may also be openings aligned above the battery cell poles.

In one aspect, the manifold structure 17 comprises a plate shaped body, and the fluid channels 18 are formed in the plate shaped body. The manifold structure 17 then defines a plane perpendicular to the axes of the battery cells 11, and the plurality of fluid channels 18 are arranged so that they extend in the plane defined by the manifold structure. The manifold structure 17 can be made of any suitable material, such as a polymer, a metal, an alloy, and the like. Preferably, the manifold structure 17 is made of materials such as EPDM, Neoprene, Polyamide. The manifold structure 17 can be made by Injection molding, extrusion, 3D-iExtrusion® technology, milling, stamping, water cutting or laser cutting or a similar manufacturing process. The manifold structure 17 has a bottom surface 19 facing the distributor plate 14. The distributor plate 14 and the manifold structure 17 are arranged substantially parallel with the first and second walls 3a-b of the casing. The distributor plate 14 and the manifold structure 17 can be arranged above the upper ends of the battery cells 11, and/or below the lower ends of the battery cells 11.

The distributor plate 14 is disposed between the manifold structure 17 and the stack 5 of battery cells 11. In one aspect, the distributor plate 14 is attached to the manifold structure 17. In another aspect, the distributor plate can be integrated into the manifold structure. In another aspect the distributor plate is combined with an electrical connector to form a connector plate. In one aspect, a cell holder can be arranged between the stack of battery cells and the distributor plate. Regardless of how the connections to the individual battery cells 11 is formed a fuse can be provided for each cell to enable disconnection of a mal-functioning battery cell 11. In case a connector plate is used, the fuses can be formed in the connector plate.

The casing 2 encloses the stack 5 of battery cells 11 and the distributor plate 14. The manifold structure 17 can be integrated in one of the first and second walls 3a-b of the casing 2. The manifold structure 17 can be integrated into a lid of the casing. The lid can, for example, be the first wall 3a. Alternatively, the manifold structure 17 can be disposed between one of the first and second walls 3a-b and the distributor plate 14. In such case, the manifold structure 17 has an upper surface facing the wall 3a-b of the casing, and the manifold structure 17 can be attached to one of the first and second walls 3a-b.

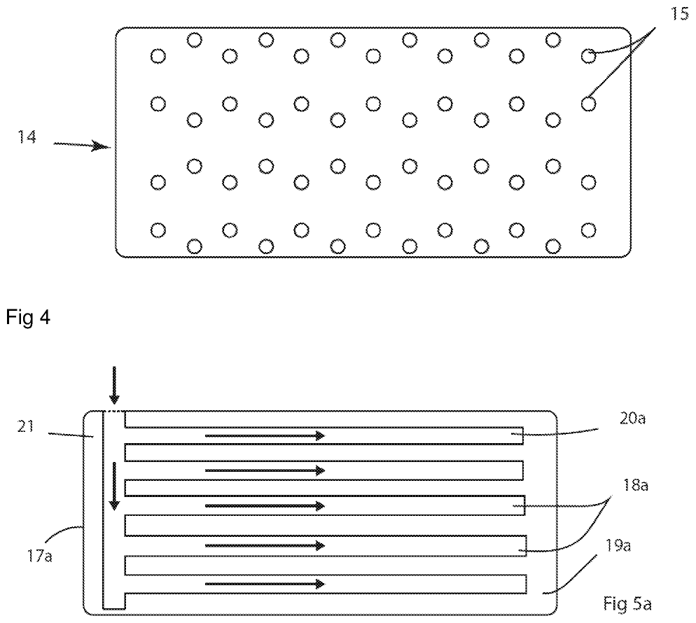

FIG. 4 shows an example of a distributor plate 14 including a plurality of openings 15. The openings 15 in the distributor plate are arranged above and below the spaces 12 so that the flow of fluid is guided towards the spaces 12 between the battery cells. Thus, the position of the openings depends on the configuration of the battery cells. Preferably, the openings 15 are substantially evenly spread over the distributor plate. Thus, the fluid can be evenly distributed between the battery cells. The number of openings 15 may vary in dependence of the number of battery cells 11 in the battery module. The location of the openings 15 varies in dependence of the shape and location of the battery cells and the space between them. The size and shape of the openings 15 may vary in dependence on the size and shape of the spaces 12 between the battery cells. In the illustrated embodiment, the openings are circular. However, the openings 15 may have other shapes, such as rectangular, triangular, or Y-shaped. The distributor plate 14 can be flexible, rigid, or semirigid. In another aspect a combination of at least two distributor plates can be used, where one distributor plate is made of rigid material and the other(s) of flexible or semi-rigid material. The distributor plate 14 can be made of any suitable material, such as a polymer, a metal, an alloy, and the like. Preferably, the distributor plate is made of a flexible material, such as EPDM, Neoprene, Polyamide. In one aspect, the distributor plate can be made of an electrically conducting material, such metal or metal alloy, flexifilm or PCB and has an additional function as electrical connector.

The manifold structure 17 including the fluid channels 18 can be designs in different ways. FIGS. 5a-c show three examples of different manifold structures 17a-c. The FIGS. 5a-c show the bottom surfaces 19 of the manifold structures 17a-c.

FIG. 5a shows a first example of a manifold structure 17a in a view from below. The manifold structure 17a comprises a plurality of straight fluid channels 18a extending from the first end 2a to the second end 2b of the casing 2. Each of the fluid channels 18a has an open side facing the distributor plate 14. The open sides of the fluid channels 18a define elongated openings 20a in the bottom surface 19a of the manifold structure 17a. The elongated openings 20a are facing the distributor plate 14 and the openings 15 in the distributor plate. The elongated openings 20a extend over the openings 15 in the distributor plate from the first end 2a to the second end 2b of the casing 2 so that the openings 15 in the distributor plate are in fluid communication with the channels 18a. The distributor plate 14 can be tightly attached to the manifold structure 17a so that the parts of the elongated openings 2a, which do not face the openings 15 in the distributor plate, are sealed by the distributor plate 14. The distributor plate 14 forms the bottoms of the fluid channels 18a. The elongated openings 20a in the manifold structure 18a are arranged so that they face the openings 15 in the distributor plate so that the fluid in the fluid channels 18a can leave the channels through the openings 15 in the distributor plate. In this example, each of the elongated opening 20a in the manifold structure faces more than one of the openings 15 in the distributor plate. Thus, one fluid channel 18a supplies fluid to a plurality of openings 15 in the distributor plate. The upper sides of the fluid channels 18a can be closed or open. If the upper sides of the fluid channels 18a are closed, the manifold structure 17a can be integrated into one of the first and second walls 3a-b. The manifold structure 17a comprises an inlet channel 21 arranged perpendicular to the fluid channels 18a and in fluid communication with the fluid channels 18a for supplying the fluid channels with fluid. The inlet channel 21 has an inlet opening arranged in fluid communication with the inlet entrance 8 of the casing for receiving the fluid. Alternatively, if the manifold structure is integrated into one of the walls of the casing, the inlet opening of the inlet channel 21 is the inlet entrance 8.

FIG. 5b shows a second example of a manifold structure 17b in a view from below. The manifold structure 17b comprises a plurality of fluid channels 18b. In this example, the fluid channels 18b branches into a plurality of narrower fluid channels 18b′. The fluid channels 18b will become narrower closer to the ends of the fluid channels. The cross-section areas of the fluid channels 18b are decreasing further away from the fluid entrance. Each of the fluid channels 18a has an open side facing the distributor plate 14. The open sides the fluid channels 18b define elongated openings 20b in the bottom surface 19b of the manifold structure 17b. The elongated openings 20b in the fluid channels 18b faces the openings 15 in the distributor plate so that the openings 15 in the distributor plate are in fluid communication with the channels 18b. The distributor plate 14 is attached to the manifold structure 17b so that the elongated openings 20b in the bottom surface 19 of the manifold structure are partly sealed by the distributor plate. Each elongated opening 20b in the manifold structure faces one or more of the openings 15 in the distributor plate. The upper sides of the fluid channels 18b can be closed or opened. If the upper sides of the fluid channels 18b are closed, the manifold structure 17b can be integrated into one of the first and second walls 3a-b. If the upper sides of the fluid channels 18b are opened, the manifold structure 17b can be attached to any of the first and second walls 3a-b so that the upper sides of the fluid channels 18b are sealed by the wall of the casing. In this example, the fluid is supplied to a fluid channel 18b in a central portion of the manifold structure 17b.

FIG. 5c shows a third example of a manifold structure 17c in a view from below. The manifold structure 17c comprises a plurality of fluid channels 18c. In this example, the fluid channels 18c branches into a plurality of narrower fluid channels 18c′. The fluid channels 18b will become thinner closer to the end of the channels. The cross-section areas of the fluid channels 18c are decreasing further away from the fluid entrance. The fluid channels 18c are smoothly bent, as seen in FIG. 5c. The shape of the channels 18c is balanced through the smooth bends to avoid turbulence and to control the pressure. Sharp bents of the channels 18c are avoided. The fluid channels 18c may extend over one or more of the openings 15 in the distributor plate so that the openings 15 in the distributor plate are in fluid communication with the channels 18c. In one aspect, each of the branches of the fluid channels 18c ends in one of the openings 15 in the distributor plate.

Each of the fluid channels 18c has an upper side facing the first wall 3a and a lower side facing the distributor plate 14. In this example, the upper sides as well as the lower sides of the fluid channels 18c are opened. Thus, the fluid channels 18c define elongated openings 20c in the manifold structure. The upper sides of the channels 18c form elongated openings in a top surface of the manifold structure. The lower sides of the channels 18c are opened and form elongated openings 20c in the bottom surface 19c of the manifold structure 17c.

In one example, the manifold structure 17c is arranged between the distributor plate 14 and the first wall 3a. The distributor plate 14 is tightly attached to the bottom surface 19 of the manifold structure 17c so that the elongated openings 20c in the bottom surface of the manifold structure are partly sealed by the distributor plate 14. The upper surface of the manifold structure 17c is tightly attached to the first wall 3a so that the elongated openings in the top surface of the manifold structure are sealed by the first wall 3a. Thus, the first wall 3a and the distributor plate 14 seal the fluid channels 18c in the manifold structure. Thus, the fluid channels 18c are defined by the first wall 3a, the manifold structure, and the distributor plate 14. This aspect facilities manufacturing of the fluid channels.

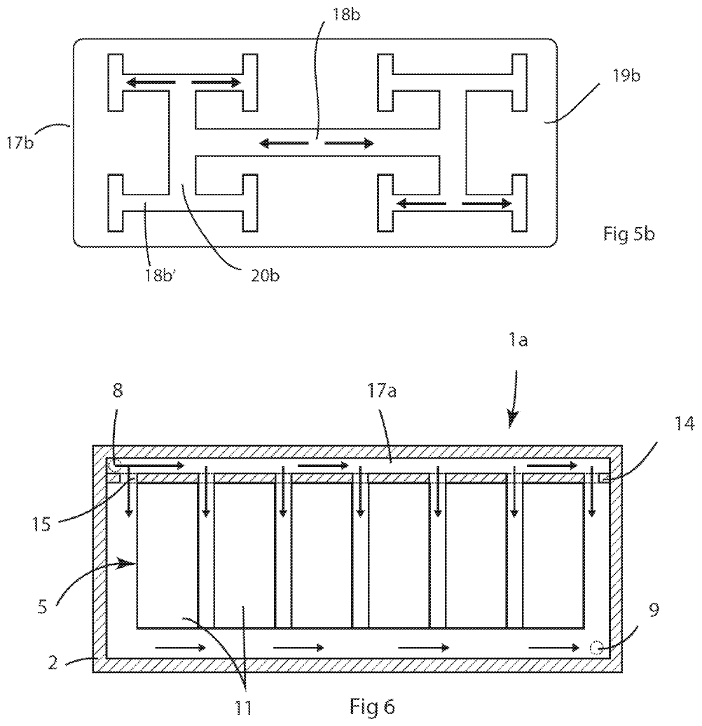

FIG. 6 shows an example of a battery module 1a including the manifold structure 17a shown in FIG. 5a. In this example, the manifold structure 17a is integrated into the first walls 3a of the casing. In this example, the fluid entrance 8 is disposed in the front wall 3e of the casing in the vicinity of the first end 2a of the casing 2. The distributor plate 14 is attached to the manifold structure 17a. The fluid enters the casing 2 through the fluid entrance 8 and is guided by the fluid channels 18a to the openings 15 in the distributor plate 14. The fluid enters the spaces 12 between the battery cells 11 and flows parallel to the axis of the battery cells along the envelop surfaces of the battery cells. The fluid exits the casing through the fluid outlet 9 at an opposite side of the stack 5 of battery cells. In this example, the fluid outlet 9 is disposed in the front wall 3e of the casing in the vicinity of the second end 2b of the casing.

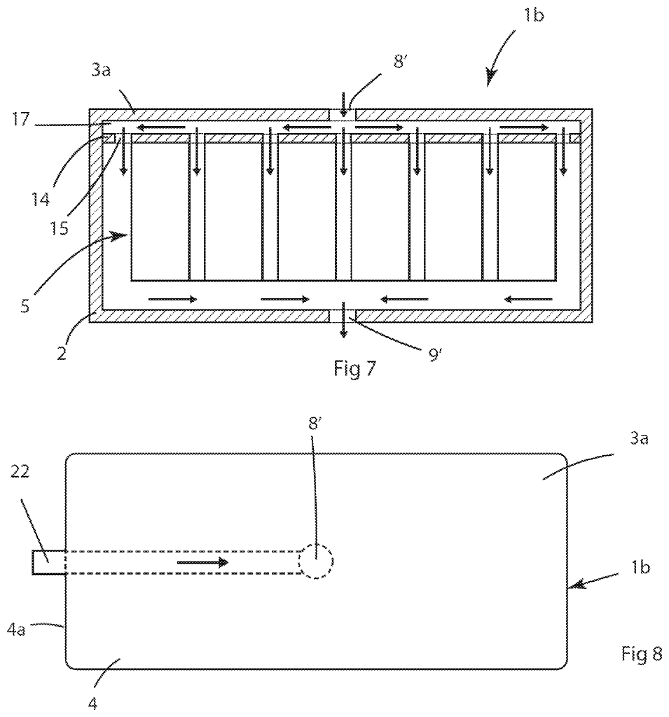

FIG. 7 shows another example of a battery module 1b including any of the manifold structure 17b-c shown in FIGS. 5b and 5c.

FIG. 8 shows the battery module 1b in FIG. 7 from above. In this example, the manifold structure 17b-c is arranged between the distributor plate 14 and the first wall 3a. The distributor plate 14 is attached to the manifold structure 17b-c, and the manifold structure 17b-c is attached to the first wall 3a. In this example, the fluid entrance 8′ is arranged in a central portion of the first wall 3a at a distance from the edges 4 of the first wall 3a, and the first wall 3a is provided with an inlet channel 22 arranged between one edge 4a of the first wall 3a and the fluid entrance 8′ for supplying the fluid to the fluid entrance 8′, as shown in FIG. 8. An inlet port 23 is connected to the fluid entrance 8′. The second wall 3b of the casing is provided with a fluid outlet 9′ for the fluid. The second fluid outlet 9′ is arranged in a central portion of the second wall 3b at a distance from the edges of the second wall 3b. The fluid enters the casing 2 through the fluid entrance 8′ and is guided by the fluid channels 18b-c to the openings 15 in the distributor plate 14. The fluid enters the spaces 12 between the battery cells and flows parallel to the axis of the battery cells 11 along the envelop surfaces of the battery cells. The fluid exits the casing 2 through the fluid outlet 9′ at the opposite side of the stack 5 of battery cells 11, as shown in FIG. 7.

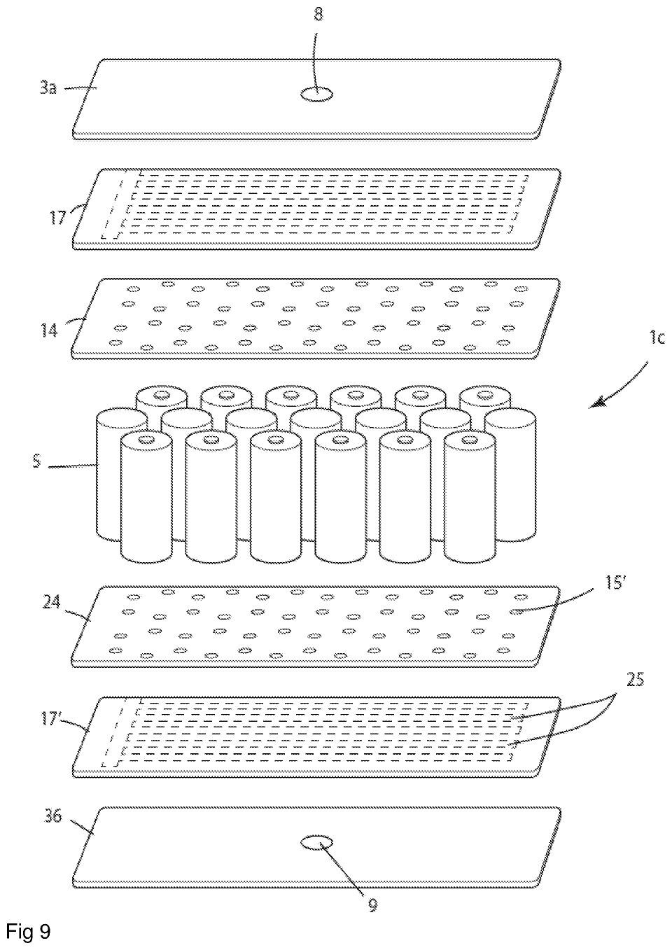

FIG. 9 shows yet another example of a battery module 1c. The battery module 1c differs from the battery module 1b disclosed in FIGS. 3 and 7 in that the battery comprises a collector plate 24 disposed between the second wall 3b and the stack 5 of battery cells on an opposite side of the stack 5 of battery cells with respect to the distributor plate 14. The collector plate 24 is provided with a plurality of openings 15′ for receiving the fluid from the spaces 12 between the battery cells 11. The openings 15′ of the collector plate 24 are preferably aligned with the openings 15 of the distributor plate 14. Preferably, the collector plate 24 is designed in the same way as the distributor plate 14. The battery module 1c further comprises a second manifold structure 17′ arranged between the collector plate 24 and the fluid outlet 9. The second manifold structure 17′ comprises a plurality of second fluid channels 12′ arranged for guiding the fluid from the openings 15′ in the collector plate 24 to the fluid outlet 9 in the second wall 3b. The second manifold structure 17′ is, for example, any of the manifold structures 17a-c shown in FIGS. 5a-c.

The battery module may also comprise one or more cell holders for holding the battery cells 11 in their positions relative each other. The cell holder ensures a minimum distance between battery cells allowing a fluid flow along the envelop surfaces of the battery cells 11 in a direction parallel with the symmetry axes of the battery cells. The holder also ensures a minimum distance to avoid short circuit.

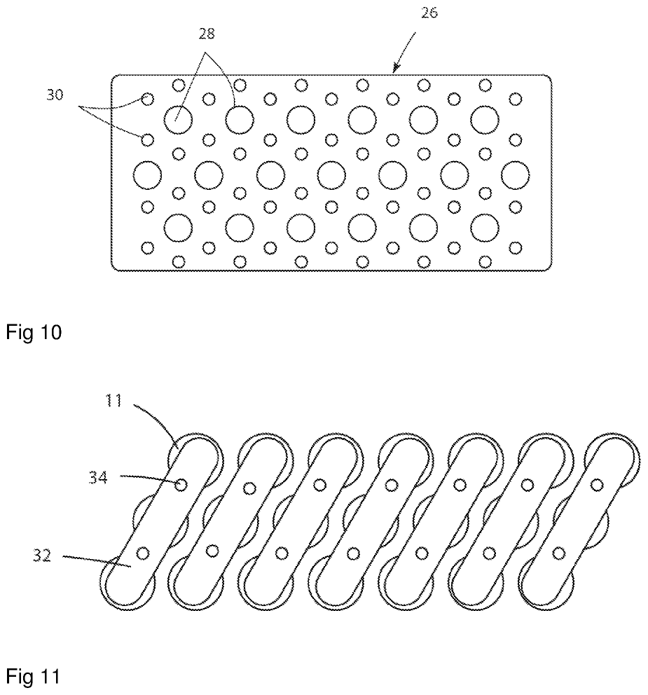

FIG. 10 shows an example of a cell holder 26. The cell holder 26 comprises a plurality of through holes 28 for receiving the battery cells 11 and a plurality of openings 30 disposed between the through holes 28 to allow the fluid to pass through the cell holder 26. Preferably, the plurality of openings 30 are aligned with the openings 15 in the distributor plate 14. Suitably, the openings 30 correspond to and have the same shape and positions as the openings 15 in the distributor plate. The cell holder 26 is disposed in the casing 2 and is adapted to receive and support the battery cells 11 in the stack 5 within the casing. In one embodiment, the battery module comprises two cell holders 26. One of the cell holders 26 is disposed at the top of the stack of battery cells, and the other cell holder is disposed at the bottom of the stack 5 of battery cells. This location of the cell holders is advantageous since the cell holders will not disturb the fluid flow along the surfaces of the battery cells. Accordingly, a laminar flow of fluid between the battery cells is achieved. The cell holder 26 can be made of any suitable material, such as a polymer, a metal, an alloy, and the like. Also, in some embodiments the cell holder 26 can be formed by the distributor plate 14.

The battery cells 11 in the stack 5 are electrically connected to each other. In one embodiment, each of the battery cells may be electrically connected to each other in a series configuration. In yet other embodiments, each of the battery cells may be electrically connected to each other in a parallel configuration, based on application requirements. The battery module comprises one or more electrical conductors, such as busbars, adapted to provide electrical connection between adjacent battery cells. Each of the battery cells is provided with poles for connection to the electrical conductor.

FIG. 11 shows an example of battery cells 11 electrically connected to each other by means of an electrical conductor 32 connected to the battery cells. In the illustrated example, the electrical conductor 32 is a busbar. The electrical conductor 32 is adapted to provide electrical connection between a plurality of neighbouring battery cells. The electrical conductor 32 is in electrical contact with the poles of the plurality of neighbouring battery cells 11. The electrical conductor 32 comprise a plurality of openings 43 to allow the fluid to pass through the electrical conductor. Preferably, the openings 43 in the electricals connector 32 are aligned with the openings 15 in the distributor plate. The battery module may comprise one or more electrical conductors 32. The electrical conductor 32 can be arranged on top of and/or below the battery cells 11. The electrical conductor 32 may be made of any electrically conductive material, such as a metal, an alloy, and the like. For example, the electrical conductor 32 is a metal foil, or a laminate of polymer and electric wirings. The electrical conductor 32 can also be connected to the one or more electric ports 10. For example, the distributor plate 14 can be made of an electrically conducting material and be used as the electrical conductor 32. In one aspect, the electrical conductor 32 is the distributor plate 14.

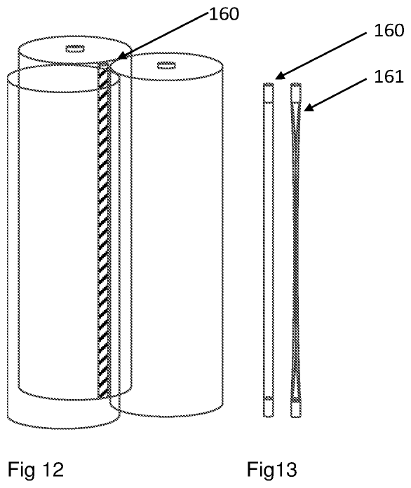

In order to improve the liquid cooling, the liquid flow inside the liquid cooled module 1;1a;1b;1c can comprise restricting members in the spaces 12 formed between the heat generating components 11. This is shown in FIG. 12.

In FIG. 12 restricting members in the form of elongated elements 160 are shown located in the spaces 12 formed between cylindrical heat generating components 11. The restricting members in the spaces 12 can have multiple purposes. For example, by locating a restricting member 160 between cylindrical heat generating components 11, the liquid flow around the cylindrical heat generating components can be improved in that the liquid is forced to have its main flow closer to the heat generating component 11 and thereby improve the heat dissipation from the heat generating component. While the restricting members 160 are located in the spaces 12 they are not obstructing the axial flow along the sides of the battery cells 12. The restricting members will instead re-distribute the flow around the heat generating components 12. In other words, the restricting members 160 will re-configure the shape of the spaces 12 so the flow channels formed in the spaces 12 will have another shape. There will still be an axial path that is unobstructed to support a free flow of the colling liquid/fluid used to cool the heat generating components 12. Thus, the shape of the flow channels in the spaces 12 can in this way be changed. The fluid is then moved in an axial direction in fluid channels formed in the spaces (12). The length of the fluid channels then corresponds to the axial length of the heat generating components. In other embodiments the fluid channels extend almost the length of the heat generating components such as at least 80% of the length of the heat generating components.

The restricting members 160 can also serve as an electric isolator and be made from an isolating material. The restricting member can also serve as a distance member to keep the heat generating components in place at a desired location. Thus, the heat generating components such as battery cells can be fixed in relation to each other using the restricting member(s). Hereby other fixating structures can be reduced or omitted since the heat generating components can be fixed by the restricting members. This will facilitate assembly since the heat generating components, typically battery cells, do not need to be fitted to a fixating structure that, for example, can be located in the housing of a battery module.

Further, the restricting members 160 can serve as a compensating member to enable thermal expansion of the heat generating components 11. In FIG. 13 an exemplary restricting member 160 is shown. The restricting member 160 of FIG. 13 is generally cylindrical in shape and can be said to be pin shaped. By providing a hollow section inside the restricting member 160 the restricting member 160 can be made to at least partially collapse to compensate for thermal expansion of the heat generating components 11 when the restricting member 160 is located in the spaces 12 between the heat generating components. FIG. 13 shows such a collapsed restricting member 161. Also, by providing restricting members as set out herein, the total volume occupied by the liquid/fluid used to cool the heat generating components 12 can be reduced. Hereby the weight of the overall module can be reduced as less liquid/fluid is required.

As set out above, the restricting member(s) can advantageously be formed by an elastic material such as a plastic material. For example, nylon can be used. In some embodiments the elastic material can be reinforced in a suitable manner. For example, glass fibre can be used to reinforce the elastic material.

As shown in FIG. 13, the restricting members 160 can be generally cylindrical in shape. This can be particularly advantageous when the restricting members are located in spaces between cylindrical heat generating components. However, other shapes of the restricting members 160 can also be used. For example, semi-cylindrical shapes of the restricting members 160 can be used or prismatic shaped restricting members can be used. In other embodiments partial cylinders other than semi-cylinders can be used such as quarter cylinders or other types of cut cylinders or prisms. The restricting members can advantageously have the same axial length as the heat generating components 11.

Depending on the purpose of the restricting member 160 the material can be selected accordingly. For example, in accordance with some embodiments, the restricting members are formed by an elastic material. This can be useful when the restricting member should serve as a thermal expansion compensator. The restricting members can also be formed by an electric conductive material to aid in conducting electricity or the restricting members can be formed by an electrically isolating material to form an isolating member.

In accordance with some embodiments the pump for generating a flow inside the liquid cooled module can be located inside the liquid cooled module. In particular the pump for pumping the fluid is located inside the liquid sealed casing. The pump can advantageously be an Electrohydrodynamic (EHD) pump. However other types of pumps are also envisaged such as a mechanical pump, a magnetohydrodynamic pump, a centrifugal pump, an osmotic pump, a sound wave pump, a diaphragm pump, a piezoelectric pump, a peristaltic pump, a nozzle-diffuser pump, a tesla pump, a capillary pump or similar. The pump can be cylindrical in shape.

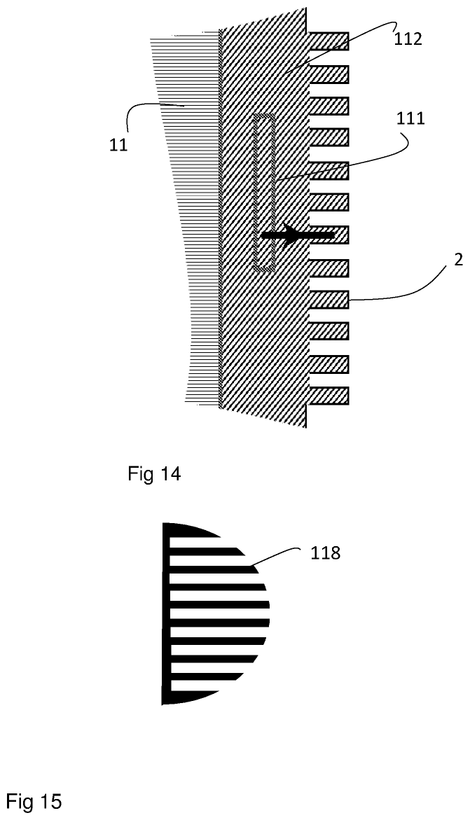

In FIG. 14 a pump 111 is shown located inside a liquid sealed casing 2. The pump can pump liquid towards or away from a heat absorbing structure. The heat absorbing structure can be a wall in the liquid cooled module. In particular the heat absorbing structure can be side wall of the liquid sealed casing 2 as is shown in FIG. 14. The side wall can be provided with fins or flanges or can have some other irregular shape or protrusions to enhance heat transfer. For example, the side wall can have a wicked or corrugated structure as is shown in FIG. 14. In FIG. 14, the pump 111 is located in a liquid 112 inside the casing 2. The liquid 112 transfers heat from heat generating components 11 disposed inside the casing 2. In some embodiments the pump 111 can be located inside a heat generating components and in some embodiments the pump is, as here located in the space 12 between such heat generating components 11.

Further, there can be multiple pumps 111 provided inside the liquid sealed casing 2. The pumps 111 can be individually controlled to support the flow of cooling liquid inside the casing 2. For example, the flow can be adjusted in response to some predetermined event. The predetermined event can for example be a thermal abnormal/undesired situation. In accordance with some embodiments, the flow of cooling liquid can be stopped or reduced in response to a determined thermal activity in the whole or some part of the liquid cooled module. For example, a temperature sensor can be provided to determine the temperature inside the liquid cooled module or some part inside the liquid cooled module. When it is determined that the temperature rises and meets some predetermined threshold value, the flow can be controlled by adjusting the pumping by the pump(s) 111. For example, the predetermined threshold value can be an absolute temperature or a pre-determined temperature increase rate. In response to such an event, the flow is then adjusted. The adjustment can be dependent on the determined event and the flow can be increased, decreased or even stopped depending on the determined event. If multiple pumps 111 are provided, the flow can be adjusted differently in different parts of the liquid cooled module by an individual adjustment of the plurality of pumps 111.

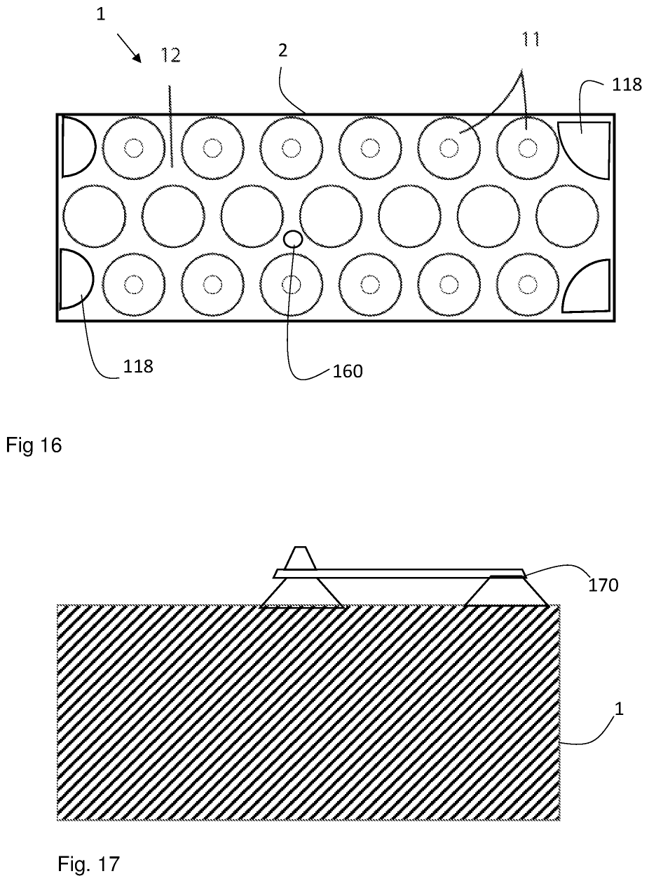

In accordance with some embodiments at least one partly cylindrical, in particular a semi cylindrical heat sink member 118 is provided located on a side wall of the casing 2 or at the bottom of the casing 2. Such an at least one partly cylindrical heat sink member 118 can be provided with a flange or flanges or some other type of protruding member. An exemplary heat sink member 118 is shown in a cross-sectional view in FIG. 15.

Other modifications to improve the working of the liquid cooled module as described herein can also be made. For example, the liquid cooled module can comprise at least one at least heater element. The heater element can be made to generate heat during for example a start phase. The heater element can be cylindrical or semi cylindrical.

In FIG. 16 a cross-sectional top view of a liquid cooled module 1 a described above is shown. The heat generating components 11 can house different kinds of components including but not limited to battery cells, motors, pumps heat generators. In the spaces between the heat generating components flow restricting members 160 can be located. The heat generating components 11 can be cylindrical as shown in FIG. 16, but could have other shapes such as a prismatic shape. There can also be components not having a cylindrical or prismatic shape. In some embodiments cut elements such as cut cylinders or prisms are located inside the liquid cooled module 1. The elements can for example be semi or quarter cylinders or prisms. The cut elements can house different components such as motor or heaters, but could also be heat sink members or thermally compensating structures. In FIG. 16 cut elements are exemplified by heat sink members 118, but they could form other types of elements as described above. The cut elements 118 can typically be located at the rim of the liquid cooled casing 2 to make better use of the space inside the casing 2. The cut elements 118 can in some embodiments be attached to the casing. In some other embodiments the cut elements are not connected to the casing 2.

Also, the cut elements 118 can be used to improve the flow inside the casing 2. The cut elements can then be part of the casing and shaped to improve the liquid flow inside the casing 2.

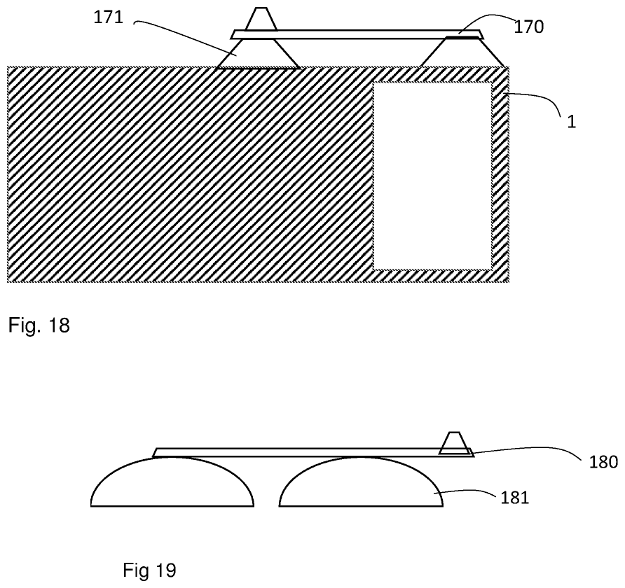

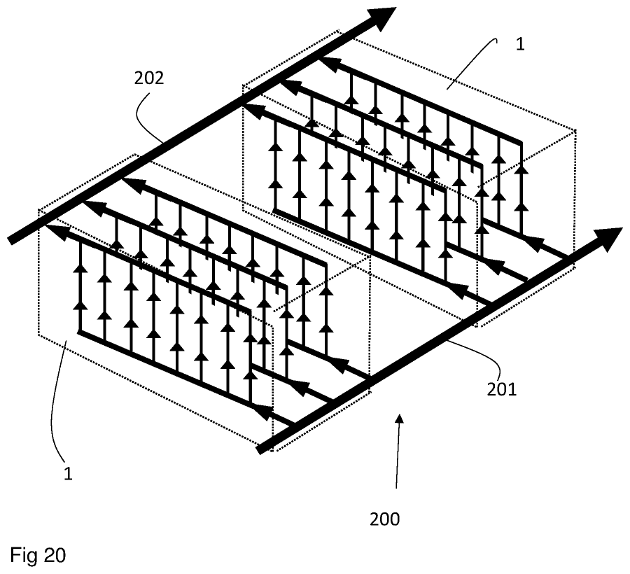

In order to further improve the efficiency of the liquid cooled module 1 as described herein a bubble trap arrangement can be added to remove air from the liquid flowing inside the liquid cooled module. In FIG. 17, a bubble trap arrangement 170 is shown for a liquid cooled module 1 without an inlet/outlet. The bubble trap arrangement can also be used when the liquid cooled module 1 is provided with a liquid inlet and a liquid outlet as is shown in FIG. 18.

The bubble trap arrangement 170 can be of different types. In FIG. 19, a bubble trap arrangement 180 of a different kind is shown. Thus, in the embodiment of FIGS. 17 and 18 one or more air bubble trap structure is provided a top section of the air bubble trap arrangement. In the embodiment of FIGS. 17 and 18 the air bubble trap structure 171 is shaped as a cut off cone or pyramid. In the embodiment of FIG. 19 the at least one air bubble trap structure 181 is shaped as a half sphere.

In FIG. 20 an exemplary embodiment of a plurality of battery modules 1 stacked to form a battery 200 is shown in a simplified view. The plurality of battery modules 1 are fluidly connected such that a common feed of cooling liquid is provided. The common feed is supplied via a common liquid inlet 201. The cooling liquid is distributed over the plurality of battery modules in a parallel configuration. Hereby cooled liquid essentially being equally cooled can enter the different battery modules 1. When the cooling liquid exits the respective battery modules 1, the cooling liquid can be supplied to a common outlet 202. Hereby a space efficient cooling circuit can be obtained. A battery 200 can for example be used in the HVAC system of a vehicle or some other electrified installation.

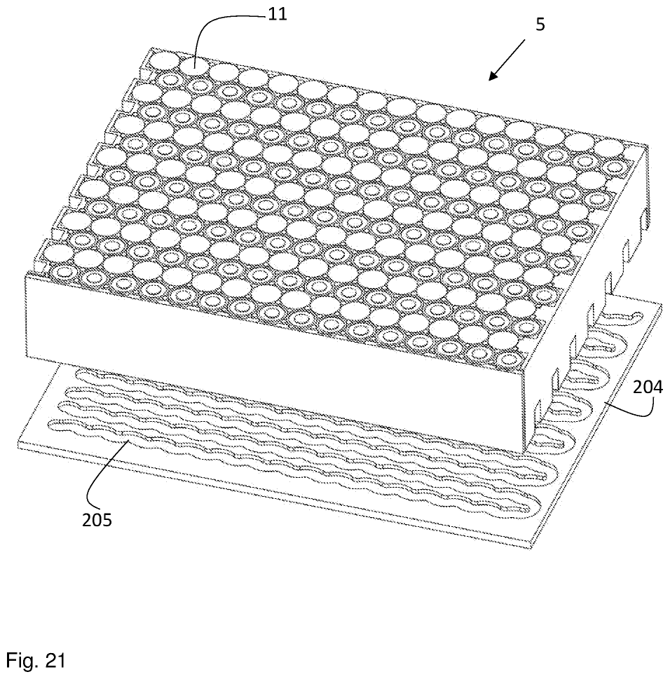

The cooling liquid in the respective battery modules can in accordance with some embodiments be distributed by forming channels for distributing cooling liquid in the top section and/or bottom of the casing 2. In FIG. 21 an exploded view illustrating parts of a battery module 1 are shown. In FIG. 21 the battery cells are shown together with the casing bottom 204. The casing bottom 204 is part of a water tight casing the casing bottom 204 has channels 205 formed on the inside thereof. The channels distribute cooling liquid over the plurality of battery cells 11 that can form a stack 5. In some embodiments the channels 205 are connected to a common inlet 201 and to a common outlet 202 as illustrated in FIG. 20. Further, the channels can have a meandering shape such that when cooling fluid is distributed over a row of battery cells 11, the cooling fluid flows in a meandering pattern along the row of mattery cells in a battery stack 5. In FIG. 21 the channels 205 are formed in the casing bottom 204. However, it is also envisaged that channels can be formed in the casing top in a corresponding manner.

While the module as described herein is typically liquid cooled, it is also envisaged that a gas is used instead of a liquid to transport heat within the module. In such an embodiment where the fluid is gas instead of a liquid, the fluid is in gas form and moved by at least one silent ion-wind-based pump. The module can then comprise at least one silent ion-wind enhanced flanged heat sink structure on the external casing walls.

The present invention is not limited to the embodiments disclosed but may be varied and modified within the scope of the following claims. For example, the flow channels can be designed in different ways. The liquid cooled module is advantageous for cooling many types of heat generating components. Also, different embodiments can be combined to enhance the cooling capacity of the liquid cooled module or to meet other needs such as making the liquid cooled module lighter or smaller. For example, the liquid cooled module may comprise two or more distributor plates arranged on top of each other. Different aspects of the embodiments disclosed can be combined with each other. For example, the distributor plate can be an integrated in the manifold structure so that the manifold structure and the distributor plate can be manufactured in one piece. For example, the electrical conductor may function as distributor plate. Also, the distributor plate can have flanges or funnels to increase cooling and or to enhance distribution of liquid.

### REFERENCE LIST

1, 1a, 1b, 1c battery module
2 casing
2a First end of the casing
2b Second end of the casing
3a-f walls of the casing
4, 4a edge of the first wall
5 stack of battery cells
8, 8′ fluid entrance
9, 9′ fluid outlet
10 electric ports
11 battery cells/heat generating component
12 Spaces between the cells
14 restricting member/distributor plate
15 openings in the distributor plate
15′ openings in the collector plate
17, 17a-c restricting member/manifold structure
17′ second manifold structure
18, 18a-c, 18b′, 18c′ fluid channels
19, 19a-c bottom surface of manifold structure
20a-c elongated openings in the manifold structure
21 inlet channel of the manifold structure
22 inlet channel of the first wall
23 Inlet port
24 collector plate
25 second fluid channels
26 cell holder
28 through holes
30 openings in the cell holder
32 Electrical connector
43 openings in the electrical connector
111 pump
112 liquid/fluid
118 cut element/heat sink member
160, 161 restricting member/pin
170, 180 Bubble trap arrangement
171, 181 air bubble trap structure
200 battery with multiple battery modules
201 common fluid inlet
202 common fluid outlet
204 casing bottom
205 channel

1. A liquid cooled module comprising:
a plurality of heat generating components arranged so that spaces for housing a moving fluid are formed around the heat generating components,
a liquid sealed casing enclosing the heat generating components, wherein at least one restricting member located in said spaces for housing a moving fluid.

2. The liquid cooled module according to claim 1, wherein the fluid is moved in an axial direction in fluid channels formed in the spaces and where no inflicting structures are located in the way for the axial flow of the fluid.

3. The liquid cooled module according to claim 1, wherein a pump for pumping the fluid is located inside the liquid sealed casing.

4. The liquid cooled module according to claim 3, wherein the pump is an Electrohydrodynamic pump.

5. The liquid cooled module according to claim 3, wherein the pump is cylindrical in shape.

6. The liquid cooled module according to claim 1, wherein the at least one restricting member is pin shaped.

7. The liquid cooled module according to claim 1, further comprising a distributor plate disposed between the casing and the heat generating components the distributor plate being provided with a plurality of openings for distributing the fluid to the spaces between the heat generating components and a manifold structure comprising a plurality of fluid channels arranged between the at least one fluid entrance and a distributor plate to guide the fluid from the at least one fluid entrance to the openings in the distributor plate.

8. The liquid cooled module according to claim 7, wherein each of the fluid channels has an open side facing the distributor plate, and the distributor plate is tightly attached to the manifold structure so that the open sides of the channels are partly sealed by the distributor plate.

9. The liquid cooled module according to claim 7, wherein the distributor plate is made of an electrically conducting material and is configured to act as an electrical connector.

10. The liquid cooled module according to claim 1, further comprising at least one at least partly cylindrical shaped thermal expansion compensating structure.

11. The liquid cooled module according to claim 1, wherein the restricting members are formed by an elastic material.

12. The liquid cooled module according to claim 1, wherein the restricting members are formed by an electric conductive material.

13. The liquid cooled module according to claim 1, wherein the liquid sealed casing comprises flanges and or at least one corrugated section.

14. The liquid cooled module according to claim 1, further comprising at least one partly cylindrical heat sink member located on a wall of the casing or at the bottom of the casing, wherein the at least one partly cylindrical heat sink member is provided with at least one flange.

15. The liquid cooled module according to claim 1, wherein the at least one restricting member comprise a hollow section allowing compression of the restricting members.

16. The liquid cooled module according to claim 1, wherein the at least one restricting member is formed by an electrically isolating material.

17. The liquid cooled module according to claim 1, wherein the plurality of heat generating components are cylindrical in shape.

18. The liquid cooled module according to claim 1, when a manifold structure is provided and where the manifold is an integrated part of the casing.

19. The liquid cooled module according to claim 1, wherein the fluid is moved in an axial direction in fluid channels formed in the spaces and where the length of the fluid channels correspond to the axial length of the heat generating components.
